(19) United States
(12) Patent Application Publication
(10) Pub. No.: US 2026/0209258 A1
(43) Pub. Date: Jul. 23, 2026

(54) MOLYBDENUM COMPOUND, METHOD FOR PREPARING SAME, AND COMPOSITION COMPRISING SAME FOR THIN FILM DEPOSITION

(71) Applicant: DNF CO., LTD., Daedeok-gu, Daejeon (KR)

(72) Inventors: Yonghee KWONE, Daedeok-gu, Daejeon (KR); Youngjae IM, Daedeok-gu, Daejeon (KR); Sangyong JEON, Daedeok-gu, Daejeon (KR); Taeseok BYUN, Daedeok-gu, Daejeon (KR); Sangchan LEE, Daedeok-gu, Daejeon (KR); Sangick LEE, Daedeok-gu, Daejeon (KR)

(21) Appl. No.: 18/718,365

(22) PCT Filed: Dec. 1, 2022
(86) PCT No.: PCT/KR2022/019323

§ 371 Date: Jun. 10, 2024

(30) Foreign Application Priority Data
Dec. 13, 2021 (KR) 10-2021-0177700

(51) Int. Cl. C07F 11/00; C23C 16/34; C23C 16/455

(52) U.S. Cl. CPC C07F 11/00; C23C 16/34; C23C 16/45553

(57) ABSTRACT

The present invention relates to a molybdenum compound, a method for preparing same, a composition comprising same for depositing a molybdenum film-containing thin film, and a method for manufacturing a molybdenum-containing thin film by using same. The employment of the molybdenum compound of the present invention having excellent thermal stability, high volatility, and improved vapor pressure can manufacture a molybdenum-containing thin film with a uniform thickness at an improved deposition rate.

### TECHNICAL FIELD

The present invention relates to a molybdenum compound, a preparation method of the same, a composition for depositing a thin film containing the same, a manufacturing method of a thin film using the same, and a thin film containing the same.

### BACKGROUND ART

Various organometallic precursors are used to form metal thin films. Various techniques have been used for deposition of the thin films, and examples thereof include a reactive sputtering method, an ion-assisted deposition method, a sol-gel deposition method, a metal organic chemical vapor deposition (MOCVD) method, which is a type of a chemical vapor deposition (CVD) method, and an atomic layer deposition (ALD) method, which is also called atomic layer epitaxy (ALE). The chemical vapor deposition (CVD) method and the atomic layer deposition (ALD) method have advantages of excellent composition control, high film uniformity, and excellent doping control, and may achieve excellent conformal deposition, such that a uniform film thickness may be implemented even in a highly non-planar microelectronic device geometry.

The chemical vapor deposition (CVD) method is a chemical process in which an organometallic precursor is used to form a thin film on a substrate. In a general chemical vapor deposition (CVD) method, a precursor reacts or decomposes on a surface of the substrate while passing through the substrate in a low pressure or atmospheric pressure chamber. Volatile by-products are removed by a gas stream.

The atomic layer deposition (ALD) method is a method capable of precisely controlling a thickness, implementing a uniform film thickness, and achieving excellent conformal deposition, and is a method of sequentially growing a film while a precursor reacts on a surface of a substrate. However, the biggest disadvantage of the atomic layer deposition (ALD) method is that a process speed per hour of growing a film is slow. As a method that may increase the process speed of the atomic layer deposition (ALD) method, there is a plasma enhanced atomic layer deposition (PEALD) method. The plasma enhanced atomic layer deposition (PEALD) method has an advantage of increasing reactivity at a lower temperature than in the atomic layer deposition (ALD) method. Therefore, in particular, in the case of capacitors or gate spacers, which are films having a high aspect ratio, the plasma enhanced atomic layer deposition (PEALD) method is more required.

The atomic layer deposition (ALD) method and the plasma enhanced atomic layer deposition (PEALD) method usually consist of four stages: pulse A in which a first precursor formed of an organic metal forms a single layer on a substrate; purge A in which an excessive amount of the first precursor is removed; pulse B in which a second precursor, which is a non-metal precursor, induces a reaction between the first precursor and the substrate; and purge B in which unreacted substances are removed. These four stages are repeated until a thin film having a desired thickness is obtained.

The thin film is used in a variety of important applications such as manufacturing of a semiconductor device and nanotechnology. Examples of these applications include a conductive film, a high-refractive index optical coating, an anti-corrosion coating, a photocatalytic self-cleaning glass coating, a biocompatible coating, a gate dielectric insulating film in a field-effect transistor (FET), a dielectric capacitor layer, a capacitor electrode, a gate electrode, an adhesive diffusion barrier, and an integrated circuit. In addition, the thin film is also used in microelectronic applications such as ferroelectric perovskites used in high-k dielectric oxides for dynamic random access memory (DRAM) applications, infrared detectors, and non-volatile ferroelectric random access memories (NV-FeFAMs). In accordance with continued miniaturization of microelectronic components, the need for using such a dielectric thin film has increased.

Most molybdenum precursors for use in CVD and ALD do not meet the performance required to implement a new process for manufacturing next-generation devices such as a semiconductor. Therefore, there is a need to develop a molybdenum precursor having improved thermal stability, higher volatility, improved vapor pressure, uniform deposition, and a stable deposition rate.

### DISCLOSURE

### Technical Problem

An object of the present invention is to provide a molybdenum compound and a preparation method of the same.

Another object of the present invention is to provide a composition for depositing a molybdenum-containing thin film containing the molybdenum compound.

Still another object of the present invention is to provide a manufacturing method of a molybdenum-containing thin film using the composition for depositing a molybdenum-containing thin film.

Still another object of the present invention is to provide a molybdenum-containing thin film containing 35% or more of molybdenum and 40% or more of nitrogen.

### Technical Solution

In one general aspect, there is provided a molybdenum compound represented by the following Chemical Formula 1:

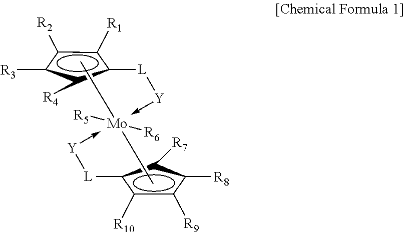

in Chemical Formula 1,
L is C1-C10 alkylene or halo C1-C10 alkylene;
R₁ to R₁₀ are each independently hydrogen or C1-C10 alkyl;
Y is —NR₁₁R₁₂, —OR₁₃, or —SR₁₄; and
R₁₁ to R₁₄ are each independently hydrogen, C1-C10 alkyl, or halo C1-C10 alkyl, or R₁₁ and R₁₂ may be linked to each other to form a ring.

According to an exemplary embodiment of the present invention, in Chemical Formula 1, L may be C1-C6 alkylene; R₁ to R₁₀ may be each independently hydrogen or C1-C6 alkyl; Y may be —NR₁₁R₁₂, —OR₁₃, or —SR₁₄; and R₁₁ to R₁₄ may be each independently hydrogen or C1-C6 alkyl, or R₁₁ and R₁₂ may be linked to each other to form a cycloaliphatic ring.

According to a preferred exemplary embodiment, the molybdenum compound may be represented by the following Chemical Formula 2:

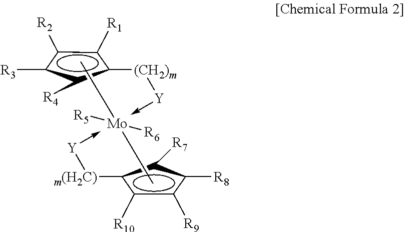

in Chemical Formula 2,
R₁ to R₁₀ are each independently hydrogen or C1-C6 alkyl;
Y is —NR₁₁R₁₂, —OR₁₃, or —SR₁₄;
R₁₁ to R₁₄ are each independently hydrogen or C1-C6 alkyl, or R₁₁ and R₁₂ may be linked to each other to form a cycloaliphatic ring; and
m is an integer of 1 to 3.

In an exemplary embodiment, the molybdenum compound may be selected from the following compounds:

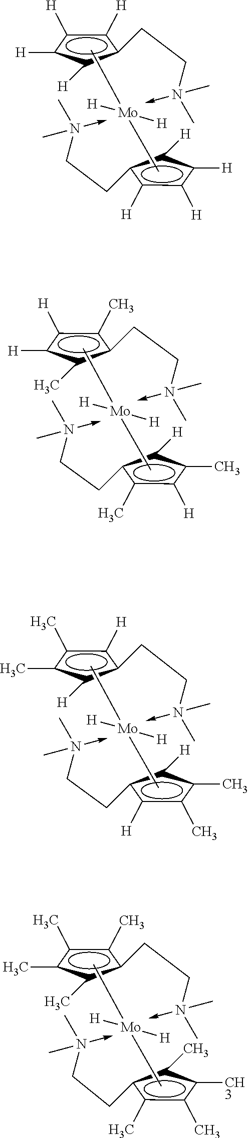

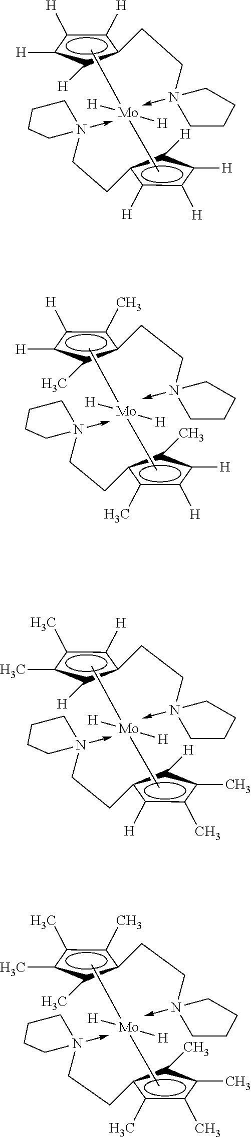

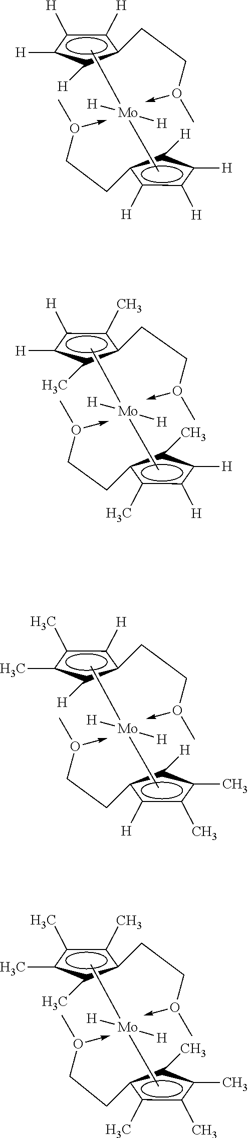

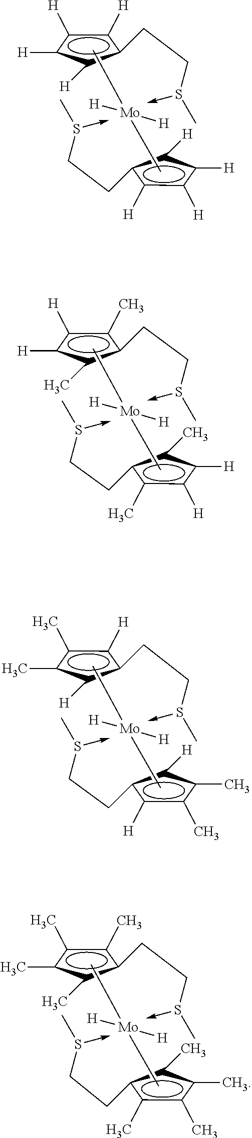

In another general aspect, a preparation method of a molybdenum compound includes preparing a molybdenum compound represented by the following Chemical Formula 1-1 by reacting a hydrogen source or alkyllithium, a compound of the following Chemical Formula 4, and a compound of the following Chemical Formula 5:

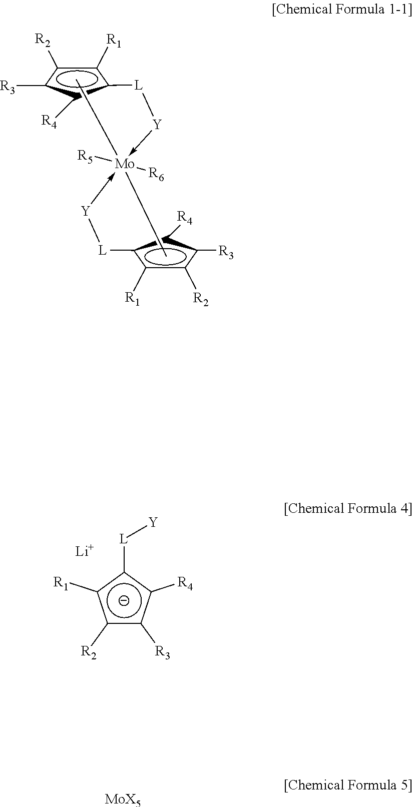

in Chemical Formulas 1-1, 4, and 5,
L is C1-C10 alkylene or halo C1-C10 alkylene;
R₁ to R₆ are each independently hydrogen or C1-C10 alkyl;
Y is —NR₁₁R₁₂, —OR₁₃, or —SR₁₄;
R₁₁ to R₁₄ are each independently hydrogen, C1-C10 alkyl, or halo C1-C10 alkyl, or R₁₁ and R₁₂ may be linked to each other to form a ring; and
X is halogen.

In still another general aspect, a composition for depositing a molybdenum-containing thin film contains the molybdenum compound.

In still another general aspect, there is provided a manufacturing method of a thin film using the composition for depositing a molybdenum-containing thin film.

The manufacturing method according to an exemplary embodiment of the present invention may include:
step a) raising a temperature of a substrate mounted in a chamber; and
step b) injecting reaction gas and the composition for depositing a molybdenum-containing thin film into the chamber to manufacture a molybdenum-containing thin film.

According to an exemplary embodiment, the reaction gas may be one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C₁ to C₁₂ saturated or unsaturated hydrocarbon, hydrogen (H₂), argon (Ar), and helium (He).

The manufacturing method according to an exemplary embodiment of the present invention may further include, after the step b), step c) injecting reaction gas into the chamber. The steps b) and c) may be set as a cycle, and the cycle may be repeatedly performed.

In still another general aspect, a molybdenum-containing thin film contains 35% or more of molybdenum and 40% or more of nitrogen.

### Advantageous Effects

As set forth above, the molybdenum compound according to the present invention has more improved thermal stability, higher volatility, and more improved vapor pressure, such that it is possible to form a thin film that has high reliability because it exhibits a stable deposition rate.

In the preparation method of a molybdenum compound according to the present invention, a high-purity molybdenum compound may be industrially and easily prepared with a high yield through a simple process.

A composition for depositing a molybdenum-containing thin film containing the molybdenum compound of the present invention is used in the manufacturing method of a molybdenum-containing thin film according to the present invention, such that high film uniformity and excellent doping controllability may be obtained by using a plasma enhanced atomic layer deposition (PEALD) method or the like. Further, the manufacturing method may provide a conformal step coverage for a three-dimensional semiconductor device.

The molybdenum-containing thin film according to the present invention contains 35% or more of molybdenum and 40% or more of nitrogen, such that an excellent composition ratio is exhibited.

### DESCRIPTION OF DRAWINGS

FIG. 1 is a photograph showing a result of measuring a molybdenum-containing thin film according to Example 1 of the present invention with a scanning electron microscope.

FIG. 2 is a photograph showing a result of measuring a molybdenum-containing thin film according to Example 2 of the present invention with a scanning electron microscope.

### BEST MODE

The present invention provides a molybdenum compound, a preparation method of the same, a composition for depositing a molybdenum-containing thin film containing the same, and a manufacturing method of a thin film using the same.

Unless the context clearly indicates otherwise, singular forms used in the present invention may be intended to include plural forms.

The expression “comprise(s)” described in the present invention is intended to be an open-ended transitional phrase having an equivalent meaning to “include(s)”, “contain(s)”, “have (has)”, and “are (is) characterized by”, and does not exclude elements, materials, or steps, all of which are not further recited herein.

The term “alkyl” described in the present invention may include both a linear form and a branched form, and may have 1 to 10 carbon atoms, and preferably 1 to 7 carbon atoms. In addition, in another aspect, the alkyl may have 1 to 4 carbon atoms.

The term “alkylene” described in the present invention refers to a divalent organic radical derived by removal of one hydrogen from “alkyl”, where the alkyl is as defined above.

The term “halo” described in the present invention refers to fluorine, chlorine, bromine, or iodine.

The term “haloalkyl” described in the present invention refers to an alkyl group in which one or more hydrogen atoms are substituted with halogen atoms. Examples of the haloalkyl include —CF₃, —CHF₂, —CH₂F, —CBr₃, —CHBr₂, —CH₂Br, —CCl₃, —CHCl₂, —CH₂Cl, —CI₃, —CHI₂, —CH₂I, —CH₂—CF₃, —CH₂—CHF₂, —CH₂—CH₂F, —CH₂—CBr₃, —CH₂—CHBr₂, —CH₂—CH₂Br, —CH₂—CCl₃, —CH₂—CHCl₂, —CH₂—CH₂Cl, —CH₂—CI₃, —CH₂—CHI₂, —CH₂—CH₂I, and the like. Here, alkyl and halogen are as defined above.

The number of carbon atoms described in alkyl and the like described in the present invention does not include the number of carbon atoms of a substituent, and as an example, C1-C10 alkyl refers to alkyl having 1 to 10 carbon atoms in which the number of carbon atoms of a substituent of the alkyl is not included.

The expression “substituted” described in the present invention means that a hydrogen atom of a moiety (for example, alkyl, aryl, or cycloalkyl) to be substituted is substituted with a substituent.

Hereinafter, the present invention will be described in detail. However, unless otherwise defined, all the technical terms and scientific terms used herein have the same meanings as commonly understood by those skilled in the art to which the present invention pertains, and descriptions for the known function and configuration unnecessarily obscuring the gist of the present invention will be omitted in the following descriptions.

The present invention provides a molybdenum compound represented by the following Chemical Formula 1:

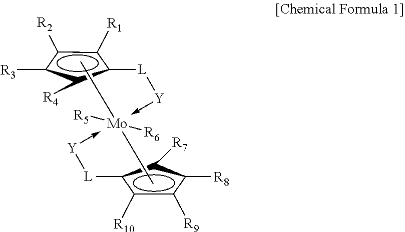

in Chemical Formula 1,
L is C1-C10 alkylene or halo C1-C10 alkylene;
R₁ to R₁₀ are each independently hydrogen or C1-C10 alkyl;
Y is —NR₁₁R₁₂, —OR₁₃, or —SR₁₄; and
R₁₁ to R₁₄ are each independently hydrogen, C1-C10 alkyl, or halo C1-C10 alkyl, or R₁₁ and R₁₂ may be linked to each other to form a ring.

The molybdenum compound represented by Chemical Formula 1 according to the present invention exhibits excellent thermal stability, high volatility, and improved vapor pressure, such that a molybdenum-containing thin film having high reliability may be obtained by employing the molybdenum compound.

In the molybdenum compound according to an exemplary embodiment of the present invention, in Chemical Formula 1, L may be C1-C6 alkylene; R₁ to R₁₀ may be each independently hydrogen or C1-C6 alkyl; Y may be —NR₁₁R₁₂, —OR₁₃, or —SR₁₄; and R₁₁ to R₁₄ may be each independently hydrogen or C1-C6 alkyl, or R₁₁ and R₁₂ may be linked to each other to form a cycloaliphatic ring.

According to a preferred exemplary embodiment, the molybdenum compound may be represented by the following Chemical Formula 2:

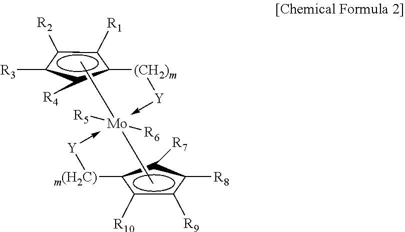

in Chemical Formula 2,
R₁ to R₁₀ are each independently hydrogen or C1-C6 alkyl;
Y is —NR₁₁R₁₂, —OR₁₃, or —SR₁₄;
R₁₁ to R₁₄ are each independently hydrogen or C1-C6 alkyl, or R₁₁ and R₁₂ may be linked to each other to form a cycloaliphatic ring; and
m is an integer of 1 to 3.

In the molybdenum compound represented by Chemical Formula 2, more specifically, R₁ to R₁₀ may be each independently hydrogen or C1-C4 alkyl; Y may be —NR₁₁R₁₂, —OR₁₃, or —SR₁₄; R₁₁ to R₁₄ may be each independently hydrogen or C1-C4 alkyl, or R₁₁ and R₁₂ may be linked to each other to form a ring; and m may be an integer of 2 or 3.

According to a more preferred exemplary embodiment, the molybdenum compound may be represented by the following Chemical Formula 3:

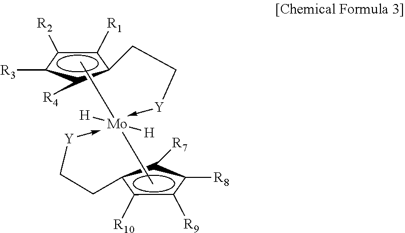

in Chemical Formula 3,
R₁ to R₄ and R₇ to R₁₀ are each independently hydrogen or C1-C4 alkyl;
Y is —NR₁₁R₁₂, —OR₁₃, or —SR₁₄; and
R₁₁ to R₁₄ are each independently hydrogen or C1-C4 alkyl, or R₁₁ and R₁₂ may be linked by C2-C6 alkylene to form a cycloaliphatic ring.

More specifically, the molybdenum compound according to an exemplary embodiment of the present invention may be represented by the following Chemical Formula 3-1:

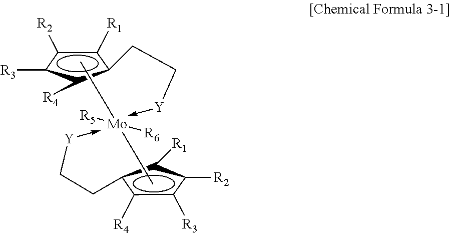

in Chemical Formula 3-1,
R₁ to R₆ are each independently hydrogen or C1-C4 alkyl;
Y is —NR₁₁R₁₂, —OR₁₃, or —SR₁₄; and
R₁₁ to R₁₄ are each independently hydrogen or C1-C4 alkyl, or R₁₁ and R₁₂ may be linked by C2-C6 alkylene to form a cycloaliphatic ring.

In an exemplary embodiment, the molybdenum compound may be selected from the following compounds, but is not limited thereto:

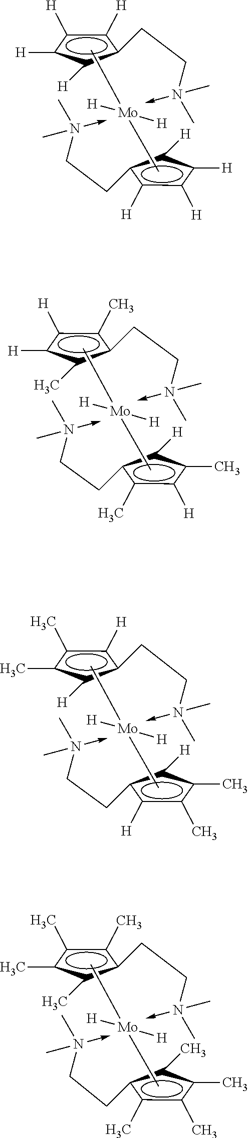

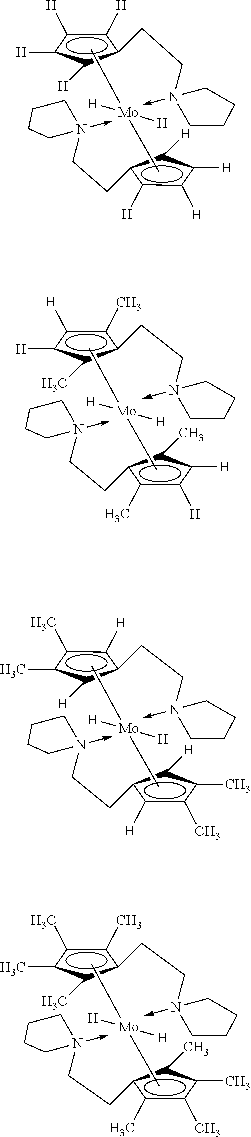

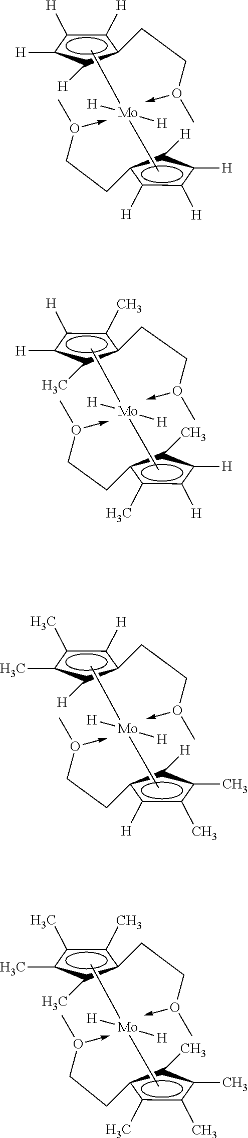

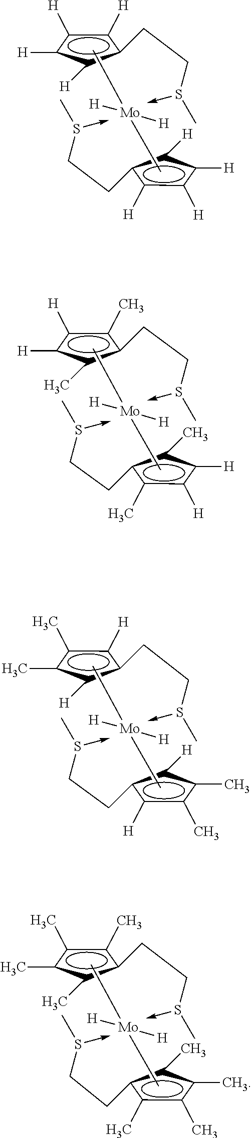

The present invention provides a preparation method of the molybdenum compound according to an exemplary embodiment of the present invention, the preparation method including preparing a molybdenum compound represented by the following Chemical Formula 1-1 by reacting a hydrogen source or alkyllithium, a compound of the following Chemical Formula 4, and a compound of the following Chemical Formula 5:

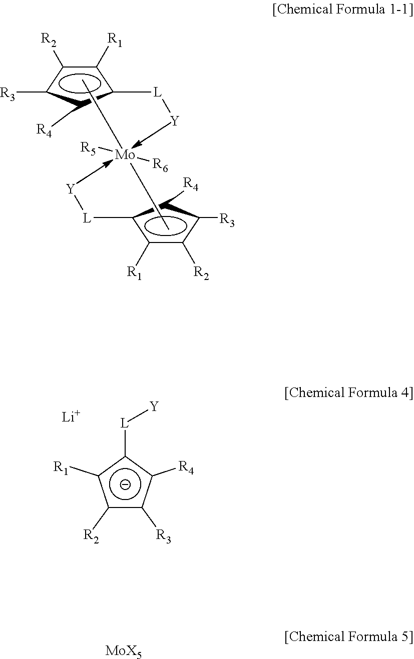

in Chemical Formulas 1-1, 4, and 5,
L is C1-C10 alkylene or halo C1-C10 alkylene;
R₁ to R₆ are each independently hydrogen or C1-C10 alkyl;
Y is —NR₁₁R₁₂, —OR₁₃, or —SR₁₄;
R₁₁ to R₁₄ are each independently hydrogen, C1-C10 alkyl, or halo C1-C10 alkyl, or R₁₁ and R₁₂ may be linked to each other to form a ring; and
X is halogen.

The compound represented by Chemical Formula 4 may be prepared by reacting alkyllithium and a compound of the following Chemical Formula 6:

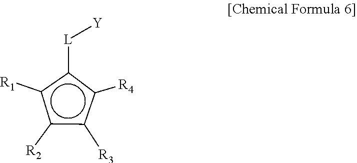

in Chemical Formula 6,
L is C1-C10 alkylene or halo C1-C10 alkylene;
R₁ to R₄ are each independently hydrogen or C1-C10 alkyl;
Y is —NR₁₁R₁₂, —OR₁₃, or —SR₁₄; and
R₁₁ to R₁₄ are each independently hydrogen, C1-C10 alkyl, or halo C1-C10 alkyl, or R₁₁ and R₁₂ may be linked to each other to form a ring.

According to an exemplary embodiment of the present invention, the hydrogen source is a compound capable of introducing hydrogen into a product through a reaction, and specifically, may be a metal hydride capable of providing a hydrogen source, and more specifically, may be one or two or more selected from CaH₂, LiAlH₄, LiBH₄, NaBH₄, NaH, LiH, and KH. More specifically, the metal hydride may be LiAlH₄ or NaBH₄, but is not limited thereto.

Specifically, the alkyllithium may be C1-C10 alkyllithium, more specifically, C1-C6 alkyllithiumm, and still more specifically, C1-C4 alkyllithium, and may be one or two or more selected from methyllithium, n-butyllithium, sec-butyllithium, tert-butyllithium, and n-hexyllithium, but is not limited thereto.

In the preparation method of a molybdenum compound, a molybdenum compound may be easily mass-prepared through a simple process.

As a solvent used in the preparation method according to an exemplary embodiment, a general organic solvent may be used, and it is preferable to use one or more selected from the group consisting of hexane, pentane, dichloromethane (DCM), dichloroethane (DCE), toluene, acetonitrile (MeCN), nitromethane, tetrahydrofuran (THF), N,N-dimethyl formamide (DMF), and N,N-dimethylacetamide (DMA).

A reaction temperature may be a temperature used in a general organic synthesis, and may vary depending on the amount of a reactant and a starting material. Preferably, the reaction may be performed at −80° C. to 20° C., specifically, −70° C. to 10° C., and more specifically, −60° C. to 5° C.

The reaction is terminated after confirming that the starting material is completely consumed through NMR or the like. Thereafter, an extraction process, a process of distilling a solvent under reduced pressure, and a process of separating and purifying a target material through a general method such as column chromatography may be performed.

A cyclopentadiene-based compound is stably coordinated to a central metal through a resonance structure, such that the thermal stability of the molybdenum compound may be significantly improved. Accordingly, the molybdenum compound according to an exemplary embodiment of the present invention may employ the cyclopentadiene-based compound to form a thin film formed of molybdenum, molybdenum nitride (MoNx), or molybdenum oxide (MoOx) with high reliability.

The cyclopentadiene-based compound may be bonded to aminoalkyl, alkoxyalkyl, or alkylsulfide. Therefore, the thermal stability of the cyclopentadiene-based compound may be further improved during a deposition process.

The present invention provides a composition for depositing a molybdenum-containing thin film containing the molybdenum compound according to an exemplary embodiment of the present invention.

In addition, the present invention provides a manufacturing method of a molybdenum-containing thin film using the composition for depositing a molybdenum-containing thin film.

The manufacturing method of a molybdenum-containing thin film may be a general method used in the art, and specifically, may be an atomic layer deposition (ALD) method, a chemical vapor deposition (CVD) method, a metal organic chemical vapor deposition (MOCVD) method, a low pressure chemical vapor deposition (LPCVD) method, a plasma enhanced chemical vapor deposition (PECVD) method, or a plasma enhanced atomic layer deposition (PEALD) method.

More preferably, the manufacturing method of a molybdenum-containing thin film according to an exemplary embodiment of the present invention may be an atomic layer deposition (ALD) method, a chemical vapor deposition (CVD) method, a metal organic chemical vapor deposition (MOCVD) method, or the like.

The manufacturing method according to an exemplary embodiment of the present invention may include:
step a) raising a temperature of a substrate mounted in a chamber; and
step b) injecting reaction gas and the composition for depositing a molybdenum-containing thin film into the chamber to manufacture a molybdenum-containing thin film.

In an exemplary embodiment, deposition conditions may be adjusted according to a structure or thermal characteristics of a desired thin film, and examples of the deposition conditions according to an exemplary embodiment include an input flow rate of the molybdenum compound, an input flow rate of reaction gas and transfer gas, pressure, and RF power.

As a non-limiting example of these deposition conditions, the input flow rate of the molybdenum compound, the input flow rate of the transfer gas, the input flow rate of the reaction gas, the pressure, and the RF power may be adjusted in ranges of 1 to 1,000 sccm, 1 to 5,000 sccm, 10 to 5,000 sccm, 0.1 to 10 torr, and 10 to 1,000 W, respectively, but are not limited thereto.

In an exemplary embodiment, the substrate mounted in the chamber in the step a) may be raised to 200° C. to 700° C., and specifically, may be raised to 500° C. to 600° C., but is not limited thereto.

According to an exemplary embodiment, the substrate may be a substrate containing one or more semiconductor materials of Si, Ge, SiGe, GaP, GaAs, SiC, SiGeC, InAs, and InP; a silicon on insulator (SOI) substrate; a quartz substrate; a glass substrate for a display; or a flexible plastic substrate formed of polyimide, polyethylene terephthalate (PET), polyethylene naphthalate (PEN), polymethyl methacrylate (PMMA), polycarbonate (PC), polyethersulfone (PES), or polyester, but is not limited thereto.

In an exemplary embodiment, the reaction gas is not limited, and may be one or a mixed gas of two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C₁ to C₁₂ saturated or unsaturated hydrocarbon, hydrogen (H₂), argon (Ar), and helium (He).

Specifically, the reaction gas may be one or two or more selected from oxygen (O₂), hydrogen peroxide (H₂O₂), nitrous oxide (N₂O), ammonia (NH₃), nitrogen (N₂), and hydrogen (H₂), and more specifically, may be ammonia (NH₃), but is not limited thereto.

In an exemplary embodiment, the transfer gas in the deposition is an inert gas, and may be one or two or more selected from argon (Ar), helium (He), and nitrogen (N₂), and specifically, may be nitrogen (N₂), but is not limited thereto.

The manufacturing method according to an exemplary embodiment may further include, after the step b), step c) injecting reaction gas into the chamber. The steps b) and c) may be set as a cycle, and the cycle may be repeatedly performed.

In an exemplary embodiment, a purge process in which transfer gas and the molybdenum compound are injected into the chamber and then the molybdenum compound or composition thereof unadsorbed on the substrate is removed using the transfer gas may be performed.

In an exemplary embodiment, a purge process in which reaction gas is injected into the chamber and then reaction by-products and residual reaction gas are removed using the transfer gas may be performed.

In an exemplary embodiment, the injection of the molybdenum compound, the purge process, the injection of the reaction gas, and the purge process may be repeatedly performed as a cycle.

The thin film manufactured by the manufacturing method of a molybdenum-containing thin film according to an exemplary embodiment is uniform and exhibits a stable deposition rate, and thus may provide a conformal step coverage for a structure having a large aspect ratio.

The molybdenum-containing thin film according to the present invention may contain 35% or more of molybdenum and 40% or more of nitrogen, preferably 35% to 65% of molybdenum and 40% to 70% of nitrogen, and more preferably 35% to 50% of molybdenum and 40% to 55% of nitrogen. The molybdenum-containing thin film according to an exemplary embodiment may exhibit an excellent composition ratio.

Hereinafter, the preparation method of a molybdenum compound and the manufacturing method of a thin film employing the same according to the present invention will be described in more detail with reference to specific Examples.

However, the following Examples are only reference examples for describing the present invention in detail, and the present invention is not limited thereto and may be implemented in various forms. In addition, the terms used in the present invention are only to effectively describe specific Examples, but are not intended to limit the present invention.

In addition, unless otherwise defined, all Examples were performed under an inert atmosphere, for example, purified nitrogen (N₂) or argon (Ar) using techniques for handling air-sensitive materials commonly known in the art.

### [Example 1] Preparation of ((CH₃)₂N(CH₂)₂Cp)₂MoH₂

To a 2 L three-neck flask including a magnetic stirrer and a reflux condenser, n-butyllithium (316 ml, 2.3 M solution in n-hexane, 0.73 mol) was added, and 500 ml of n-hexane was added, and then the mixture was stirred.

While maintaining the internal temperature of the mixture at 0° C., (2-dimethylaminoethyl)cyclopentadiene was slowly added, and then the mixture was stirred at room temperature for 2 hours. Thereafter, a solvent was removed under reduced pressure to obtain 95 g of Li(2-dimethylaminoethyl)cyclopentadiene (yield: 92%).

To a 2 L two-neck flask including a magnetic stirrer and a reflux condenser, a mixture of 95 g (0.66 mol) of Li(2-dimethylaminoethyl)cyclopentadiene and 10.8 g (0.29 mol) of LiAlH₄ was added, and 1,000 ml of THE was added, and then the mixture was stirred while maintaining the internal temperature at −50° C.

To a 2 L three-neck flask including a magnetic stirrer and a reflux condenser, MoCl₅ (78 g, 0.29 mol) was added, and 100 ml of toluene and 1,000 ml of THE were added, and then the mixture was stirred while maintaining the internal temperature at −50° C.

As a result of slowly adding a mixture of Li(2-dimethylaminoethyl)cyclopentadiene and LiAlH₄ to the mixture, heat generation and gas generation were confirmed, and a color change to dark reddish brown was observed. Thereafter, a solvent was removed under reduced pressure, and a residue was extracted with n-pentane (1,500 ml). The resulting dark red solution was filtered with a filtration device, and then a solvent was removed under reduced pressure, thereby obtaining about 43 g of ((CH₃)₂N(CH₂)₂Cp)₂MoH₂ as a dark reddish brown liquid (yield based on MoCl₅: 38%).

¹H NMR (400 MHz, C6D6) δ 4.2-4.8 (m, 8H), 2.4 (s, 8H), 2.0 (s, 12H), −8.3 (s, 2H)

### [Example 2] Preparation of ((CH₃)O(CH₂)₂Cp)₂MoH₂

To a 2 L three-neck flask including a magnetic stirrer and a reflux condenser, n-butyllithium (122 ml, 2.3 M solution in n-hexane, 0.28 mol) was added, and 300 ml of n-hexane was added, and then the mixture was stirred.

While maintaining the internal temperature of the mixture at 0° C., (2-methoxyethyl)cyclopentadiene was slowly added, and then the mixture was stirred at room temperature for 2 hours. Thereafter, a solvent was removed under reduced pressure to obtain 33 g of Li(2-methoxyethyl)cyclopentadiene (yield: 91.6%).

To a 1 L two-neck flask including a magnetic stirrer and a reflux condenser, a mixture of 95 g (0.66 mol) of Li(2-methoxyethyl)cyclopentadiene and 10.8 g (0.29 mol) of LiAlH₄ was added, and 500 ml of THE was added, and then the mixture was stirred while maintaining the internal temperature at −50° C.

To a 2 L three-neck flask including a magnetic stirrer and a reflux condenser, MoCl₅ (30 g, 0.11 mol) was added, and 50 ml of toluene and 500 ml of THE were added, and then the mixture was stirred while maintaining the internal temperature at −50° C.

As a result of slowly adding a mixture of Li(2-methoxyethyl)cyclopentadiene and LiAlH₄ to the mixture, heat generation and gas generation were confirmed, and a color change to dark reddish brown was observed. Thereafter, a solvent was removed under reduced pressure, and a residue was extracted with n-pentane (1,000 ml). The resulting dark red solution was filtered with a filtration device, and then a solvent was removed under reduced pressure, thereby obtaining about 22 g of ((CH₃)O(CH₂)₂Cp)₂MoH₂ as a dark reddish brown liquid (yield based on MoCl₅: 53%).

¹H NMR (400 MHz, C6D6) δ 4.2-4.8 (m, 8H), 3.3-3.4 (t, 4H), 3.1 (s, 6H), 2.4-2.5 (t, 4H), 3.1 (s, 6H), 1.0 (m, 2H), −8.4 (s, 2H)

### [Example 3] Manufacturing of Molybdenum-Containing Thin Film Using ((CH₃)₂N(CH₂)₂Cp)₂MoH₂

A molybdenum-containing thin film was manufactured using the molybdenum compound according to Example 1 and ammonia (NH₃) as reaction gas by a plasma enhanced atomic layer deposition (PEALD) method.

A silicon substrate on which silicon oxide was grown was loaded in a deposition chamber, and the temperature of the substrate was adjusted to 400° C. A stainless steel bubbler container was filled with ((CH₃)₂N(CH₂)₂Cp)₂MoH₂ prepared in Example 1 as an organometallic precursor, and the temperature was adjusted to 100° C.

In the plasma enhanced atomic layer deposition (PEALD) process, the process pressure was adjusted to 10 Torr or less by adjusting a throttle valve. The organometallic precursor was injected into a deposition chamber for 5 seconds using nitrogen gas as transfer gas (100 sccm). Purging was performed for 3 seconds using nitrogen gas (500 sccm) to remove the organometallic precursor and reaction by-products remaining in the deposition chamber.

Ammonia (NH₃) (2,000 sccm/RF power 400 W) as reaction gas was injected for 3 seconds to deposit a molybdenum-containing nitride thin film. Thereafter, purging was performed for 3 seconds using nitrogen gas (500 sccm) to remove residual reaction gas and reaction by-products.

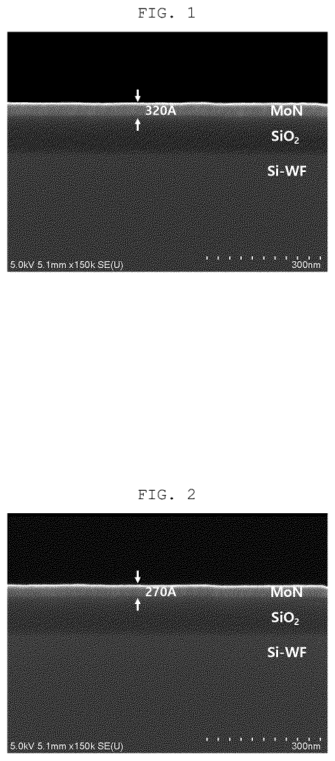

The processes described above were set as a cycle and 1,000 cycles were repeated, thereby manufacturing a molybdenum-containing nitride thin film having a thickness of 320 Å as illustrated in FIG. 1. As a result of AES analysis of the molybdenum-containing thin film, a content of molybdenum (Mo) and a content of nitrogen (N) were 41.8% and 45.4%, respectively, and it was confirmed that a molybdenum nitride film was substantially formed.

### [Example 4] Manufacturing of Molybdenum-Containing Thin Film Using ((CH₃)O(CH₂)₂Cp)₂MoH₂

A molybdenum-containing thin film was manufactured using the molybdenum compound according to Example 2 and ammonia (NH₃) as reaction gas by a plasma enhanced atomic layer deposition (PEALD) method.

A silicon substrate on which silicon oxide was grown was loaded in a deposition chamber, and the temperature of the substrate was adjusted to 400° C. A stainless steel bubbler container was filled with ((CH₃)O(CH₂)₂Cp)₂MoH₂ prepared in Example 2 as an organometallic precursor, and the temperature was adjusted to 100° C.

In the plasma enhanced atomic layer deposition (PEALD) process, the process pressure was adjusted to 10 Torr or less by adjusting a throttle valve. The organometallic precursor was injected into a deposition chamber for 5 seconds using nitrogen gas as transfer gas (100 sccm). Purging was performed for 3 seconds using nitrogen gas (500 sccm) to remove the organometallic precursor and reaction by-products remaining in the deposition chamber.

Ammonia (NH₃) (2,000 sccm/RF power 400 W) as reaction gas was injected for 3 seconds to deposit a molybdenum-containing nitride thin film. Thereafter, purging was performed for 3 seconds using nitrogen gas (500 sccm) to remove residual reaction gas and reaction by-products.

The processes described above were set as a cycle and 1,000 cycles were repeated, thereby manufacturing a molybdenum-containing nitride thin film having a thickness of 270 Å as illustrated in FIG. 2. As a result of AES analysis of the molybdenum-containing thin film, a content of molybdenum (Mo) and a content of nitrogen (N) were 41.3% and 46.5%, respectively, and it was confirmed that a molybdenum nitride film was substantially formed.

As described above, since the molybdenum compound according to an exemplary embodiment of the present invention has more improved thermal stability, higher volatility, and more improved vapor pressure, when a thin film is manufactured using the molybdenum compound, it is possible to form a thin film that has high reliability because it is uniform and exhibits a stable deposition rate, a uniform film thickness may be provided for a three-dimensional device, and a thin film exhibiting an excellent composition ratio of molybdenum and nitrogen may be manufactured.

Hereinabove, although the present invention has been described by specific matters and limited Examples and Comparative Examples, they have been provided only for assisting in the entire understanding of the present invention. Therefore, the present invention is not limited to the Examples. Various modifications and changes may be made by those skilled in the art to which the present invention pertains from this description.

Therefore, the spirit of the present invention should not be limited to the described Examples, but the claims and all modifications equal or equivalent to the claims are intended to fall within the spirit of the present invention.

1. A molybdenum compound represented by the following Chemical Formula 1: 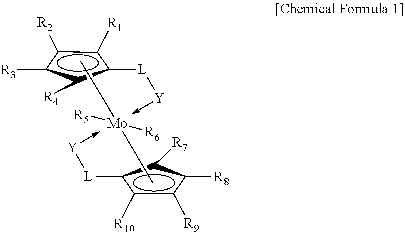
in Chemical Formula 1,
L is C1-C10 alkylene or halo C1-C10 alkylene;
R₁ to R₁₀ are each independently hydrogen or C1-C10 alkyl;
Y is —NR₁₁R₁₂, —OR₁₃, or —SR₁₄; and
R₁₁ to R₁₄ are each independently hydrogen, C1-C10 alkyl, or halo C1-C10 alkyl, or R₁₁ and R₁₂ may be linked to each other to form a ring.

2. The molybdenum compound of claim 1, wherein in Chemical Formula 1,
L is C1-C6 alkylene;
R₁ to R₁₀ are each independently hydrogen or C1-C6 alkyl;
Y is —NR₁₁R₁₂, —OR₁₃, or —SR₁₄; and
R₁₁ to R₁₄ are each independently hydrogen or C1-C6 alkyl, or R₁₁ and R₁₂ may be linked to each other to form a cycloaliphatic ring.

3. The molybdenum compound of claim 1, wherein the molybdenum compound is represented by the following Chemical Formula 2: 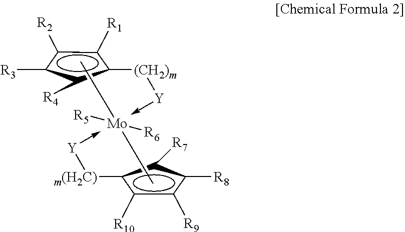
in Chemical Formula 2,
R₁ to R₁₀ are each independently hydrogen or C1-C6 alkyl;
Y is —NR₁₁R₁₂, —OR₁₃, or —SR₁₄;
R₁₁ to R₁₄ are each independently hydrogen or C1-C6 alkyl, or R₁₁ and R₁₂ may be linked to each other to form a cycloaliphatic ring; and
m is an integer of 1 to 3.

4. The molybdenum compound of claim 1, wherein the molybdenum compound is selected from the following compounds:

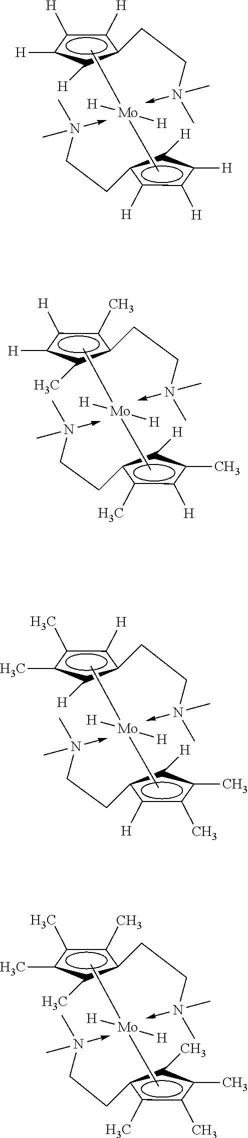

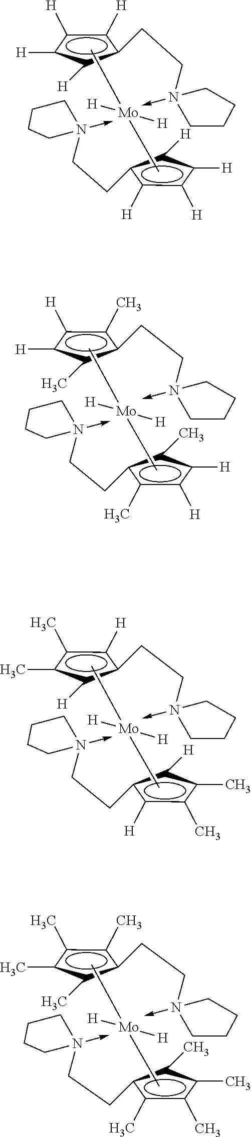

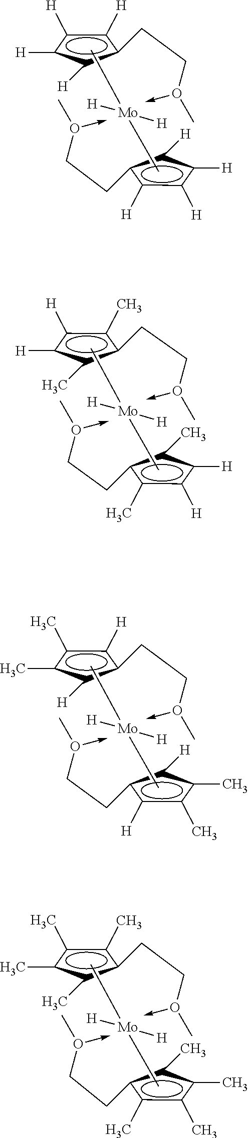

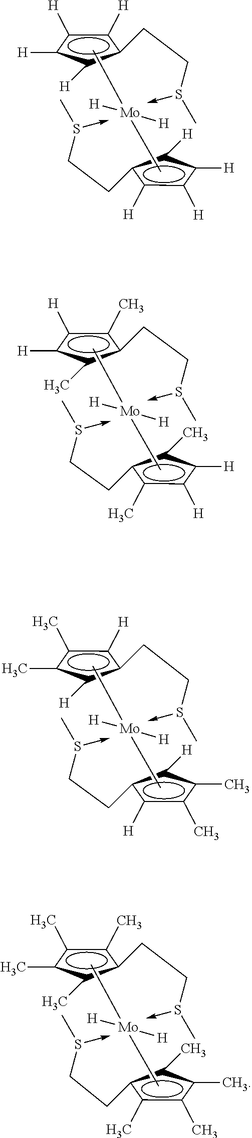

5. A preparation method of a molybdenum compound comprising preparing a molybdenum compound represented by the following Chemical Formula 1-1 by reacting a hydrogen source or alkyllithium, a compound of the following Chemical Formula 4, and a compound of the following Chemical Formula 5: 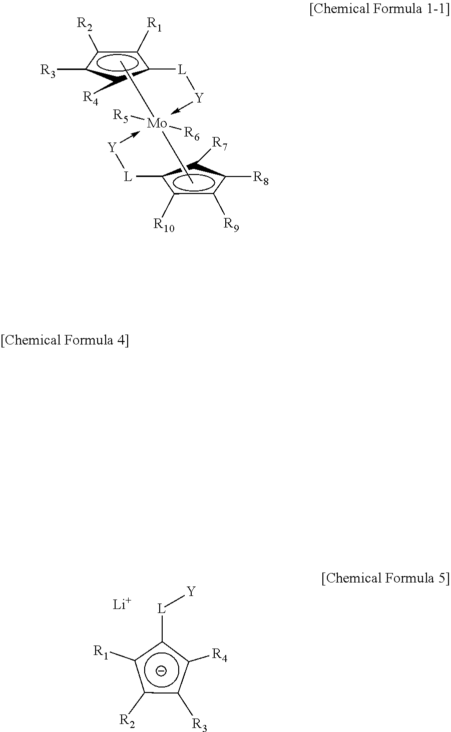
MoX₅
in Chemical Formulas 1-1, 4, and 5,
L is C1-C10 alkylene or halo C1-C10 alkylene;
R₁ to R₆ are each independently hydrogen or C1-C10 alkyl;
Y is —NR₁₁R₁₂, —OR₁₃, or —SR₁₄;
R₁₁ to R₁₄ are each independently hydrogen, C1-C10 alkyl, or halo C1-C10 alkyl, or R₁₁ and R₁₂ may be linked to each other to form a ring; and
X is halogen.

6. A composition for depositing a molybdenum-containing thin film comprising the molybdenum compound of claim 1.

7. A manufacturing method of a molybdenum-containing thin film using the composition for depositing a molybdenum-containing thin film of claim 6.

8. The manufacturing method of claim 7, wherein the manufacturing method includes:
step a) raising a temperature of a substrate mounted in a chamber; and
step b) injecting reaction gas and the composition for depositing a molybdenum-containing thin film into the chamber to manufacture a molybdenum-containing thin film.

9. The manufacturing method of claim 8, wherein the reaction gas is one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C₁ to C₁₂ saturated or unsaturated hydrocarbon, hydrogen (H₂), argon (Ar), and helium (He).

10. The manufacturing method of claim 8, wherein the manufacturing method further includes, after the step b), step c) injecting reaction gas into the chamber.

11. The manufacturing method of claim 10, wherein the steps b) and c) are set as a cycle, and the cycle is repeatedly performed.

12. A molybdenum-containing thin film comprising 35% or more of molybdenum and 40% or more of nitrogen.
